(19) United States
(12) Patent Application Publication
(10) Pub. No.: US 2026/0122827 A1
(43) Pub. Date: Apr. 30, 2026

(54) HARD DRIVE TRAY, HARD DRIVE ASSEMBLY, AND SERVER

(71) Applicant: SUZHOU METABRAIN INTELLIGENT TECHNOLOGY CO., LTD., Suzhou, Jiangsu (CN)

(72) Inventor: Zhanlin NIU, Suzhou, Jiangsu (CN)

(21) Appl. No.: 19/159,656

(22) PCT Filed: Jun. 4, 2025
(86) PCT No.: PCT/CN2025/099122

§ 371 Date: Aug. 26, 2025

(30) Foreign Application Priority Data
Sep. 26, 2024 (CN) 202411347772.2

(51) Int. Cl. H05K 7/14; F16M 13/02

(52) U.S. Cl. CPC H05K 7/1489; F16M 13/02

(57) ABSTRACT

The present disclosure discloses a hard drive tray, a hard drive assembly, and a server. The hard drive tray comprising: a tray front end body, a first slide connected to the tray front end body, a second slide connected to the tray front end body and disposed opposite to the first slide, wherein a space configured to receive a hard drive is formed between the first slide and the second slide, and a clamping column disposed on at least one of the first slide and the second slide and configured to be clamped with the hard drive, wherein at least one of the first slide and the second slide is provided with a mounting hole which is configured for a fastener to pass therethrough, and the fastener is configured to fix the hard drive.

### CROSS-REFERENCE TO RELATED APPLICATION

This disclosure claims the priority of the Chinese Patent disclosure filed on September 26, 2024 before the CNIPA, China National Intellectual Property Administration with the disclosure number of 202411347772.2, and the title of “HARD DRIVE TRAY, HARD DRIVE ASSEMBLY, AND SERVER”, which is incorporated herein in its entirety by reference.

### FIELD

The present disclosure relates to the technical field of hard drive mounting structures, and more specifically, to a hard drive tray. Furthermore, the present disclosure also relates to a hard drive assembly including the hard drive tray and a server including the hard drive assembly.

### BACKGROUND

In the technical field of servers, hard drive trays have been widely used. In use, a hard drive is installed on a hard drive tray, and then the hard drive tray is installed in a chassis, thereby realizing the installation of the hard drive.

In the first related art, after the hard drive is installed on the hard drive tray, the hard drive and the hard drive tray are fixed using a plurality of screws. However, this manner of fixing the hard drive requires use of a tool for installation, and a large number of screws need to be installed, which is very inconvenient for installation and affects the assembly efficiency.

In the second related art, a hard drive tray installed completely without tools is used, and its structure is relatively complex.

### SUMMARY

In view of the above problems, an objective of the present disclosure is to provide a hard drive tray which is convenient to install and has a simple structure.

Another objective of the present disclosure is to provide a hard drive assembly including the hard drive tray, which is convenient to assemble with high assembly efficiency.

Further another objective of the present disclosure is to provide a server including the hard drive assembly which has high assembly efficiency and good maintenance applicability.

To achieve the foregoing objective, the present disclosure provides a hard drive tray. The hard drive tray including: a tray front end body, a first slide connected to the tray front end body, a second slide connected to the tray front end body and disposed opposite to the first slide, wherein a space configured to receive a hard drive is formed between the first slide and the second slide, and a clamping column disposed on at least one of the first slide and the second slide and configured to be clamped with the hard drive, wherein at least one of the first slide and the second slide is provided with a mounting hole which is configured for a fastener to pass therethrough, and the fastener is configured to fix the hard drive.

In an embodiment, the clamping column is closer to the tray front end body than the mounting hole along a length direction of the first slide or the second slide.

In an embodiment, the clamping column include: a first clamping column disposed on the first slide, and a second clamping column disposed on the second slide, wherein the first clamping column and the second clamping column are aligned.

In an embodiment, wherein the mounting hole include: a first mounting hole formed in the first slide, and a second mounting hole formed in the second slide, wherein the first mounting hole and the second mounting hole are aligned.

In an embodiment, the hard drive tray further including: a supporting plate connected to at least one of the first slide, the second slide and the tray front end body, extending to a bottom of a space between the first slide and the second slide, and configured to support the hard drive.

In an embodiment, the supporting plate include: a first supporting plate disposed at a bottom of the first slide and located below the first clamping column, and a second supporting plate disposed at a bottom of the second slide and located below the second clamping column.

In an embodiment, a height of one of the first slide and the second slide is greater than a height of the other, and the first slide and the second slide are configured to match a front window structure of a chassis to prevent the hard drive tray from being inserted upside down.

In an embodiment, a light guide is disposed on the tray front end body at a position corresponding to the second slide, and a front end face of the light guide is exposed in front of the tray front end body to display a working state of the hard drive, while a rear end face of the light guide is configured to match a working indicator light on a back plate of the hard drive.

In an embodiment, the hard drive tray further including a sheet metal support which include: a support arm cross beam which is of a straight hollowed-out structure and is configured to be connected to a side of the tray front end body facing the first slide and the second slide, a first support arm perpendicularly connected to one end of the support arm cross beam and in close contact with an inner sidewall of the first slide, and a second support arm perpendicularly connected to the other end of the support arm cross beam and in close contact with an inner sidewall of the second slide, wherein the first support arm and the second support arm are each provided with a through hole configured for the clamping column and the fastener to pass therethrough.

In an embodiment, the tray front end body is provided with: a handle rotatable to open or close, wherein the handle is provided with a first buckle which is configured to be fit with a second clamping groove of a server chassis to limit a position when the handle is closed, and the first buckle is disengaged from the second clamping groove when the handle is rotated to open.

In an embodiment, the handle include a first end rotatably connected to the tray front end body and a second end clamped with the tray front end body, wherein the first buckle is disposed at the first end.

In an embodiment, a plurality of first ventilation holes arranged at intervals are formed in a middle portion of the handle along a length direction thereof, a plurality of second ventilation holes arranged along the length direction are formed in the handle on two sides of the middle portion, and a third ventilation hole is formed in the tray front end body.

In an embodiment, a pressable switch is disposed on the tray front end body and is clamped with an end of the handle away from the first buckle, and when the switch is pressed, the handle is unclamped from the switch.

In an embodiment, a middle portion of the handle is of a solid structure; elongated ventilation slots are formed in the handle on two sides of the middle portion, and a fourth ventilation hole is formed in the tray front end body.

In an embodiment, an electromagnetic interference shielding elastic piece is disposed on a rear end face of the tray front end body facing the first slide and the second slide and on two sides of the tray front end body, and is of an integrated structure.

In an embodiment, the electromagnetic interference shielding elastic piece include: a middle elastic piece attached and fixed to the rear end face of the tray front end body, two side connection portions respectively connected to two sides of the middle elastic piece and configured to clamp the two sides of the tray front end body, and two side elastic pieces correspondingly connected to the two side connection portions, respectively bent towards sides away from the tray front end body, and extending towards sides where the first slide and the second slide are located, wherein a middle portion of each side elastic piece has a projection protruding away from the tray front end body, and an end of each side elastic piece away from the side connection portion has a bent portion bent towards a side where the tray front end body is located; the middle elastic piece, the two side connection portions and the two side elastic pieces are formed by bending an integral piece, and the electromagnetic interference shielding elastic piece is of a hollowed-out structure as a whole.

In an embodiment, a limiting protrusion is disposed on the tray front end body, and a limiting hole is formed in the middle elastic piece and is fit with the limiting protrusion to limit a position.

To achieve the foregoing objective, the present disclosure provides a hard drive assembly. The hard drive assembly including: a hard drive and the hard drive tray according to any one of the embodiment, wherein the hard drive is disposed between the first slide and the second slide of the hard drive tray.

To achieve the foregoing objective, the present disclosure provides a server. The server including a chassis and the hard drive assembly, wherein the hard drive assembly is inserted into the chassis.

The hard drive tray provided in the present disclosure has the following beneficial effects:

The clamping column is disposed on at least one of the first slide and the second slide. After the hard drive is installed in place, the clamping column is clamped with the corresponding first clamping groove of the hard drive, thereby playing a role of assisting in fixing the hard drive. Moreover, at least one of the first slide and the second slide is provided with the mounting hole which allows the fastener for fixing the hard drive to pass therethrough. Therefore, when the hard drive is installed in place, the fastener is passed through the mounting hole and connected to the hard drive. It thus can be seen that the hard drive tray involves two combined fixing manners, namely clamping of the clamping column with the hard drive and fixing of the fastener with the hard drive, thereby realizing the fixation of the hard drive on the hard drive tray. The clamping of the clamping column with the first clamping groove of the hard drive allows for a tool-free installation structure, which only requires that the first clamping groove is aligned with the clamping column. Compared with the related art in which the hard drive is fixed completely using screws, the number of fasteners is reduced as the clamping column is used, thereby saving the installation time, improving the assembly efficiency and improving the maintenance applicability. Compared with a hard drive bracket without using an installation tool in the related art, the hard drive tray provided in some embodiments of the present disclosure has a simple structure.

That is, the hard drive tray is convenient to install while ensuring reliable fixation of the hard drive, thereby reducing the assembly time, and has a simple structure, good applicability, and high practical value.

The hard drive assembly provided in the present disclosure includes the hard drive tray described above, and has the same beneficial effects with the hard drive tray described above.

The server provided in the present disclosure includes the hard drive assembly described above, and has the same beneficial effects with the hard drive assembly described above.

### BRIEF DESCRIPTION OF THE DRAWINGS

FIG. 1 is a schematic structural diagram of a hard drive tray provided by some embodiments of the present disclosure;

FIG. 2 is a schematic structural diagram of the hard drive tray shown in FIG. 1 in which a hard drive has been installed;

FIG. 3 is an exploded view of FIG. 2;

FIG. 4 is a left view of the hard drive tray shown in FIG. 1;

FIG. 5 is a schematic structural diagram of a handle in FIG. 2 when being opened;

FIG. 6 is a front view of the handle in FIG. 2 when being closed;

FIG. 7 is a schematic structural diagram of a sheet metal support;

FIG. 8 is a schematic structural diagram of the handle from a first perspective;

FIG. 9 is a schematic structural diagram of the handle from a second perspective;

FIG. 10 is a schematic structural diagram of a button;

FIG. 11 is a partially enlarged schematic diagram of a first end of the handle being connected to a tray front end body;

FIG. 12 is a partially enlarged schematic diagram of the button being connected to the tray front end body;

FIG. 13 is a schematic structural diagram of the tray front end body from a first perspective;

FIG. 14 is a schematic structural diagram of the tray front end body from a second perspective;

FIG. 15 is a schematic structural diagram of an electromagnetic interference shielding elastic piece;

FIG. 16 is a schematic structural diagram of the electromagnetic interference shielding elastic piece being assembled with the tray front end body;

FIG. 17 is a schematic structural diagram of a first slide, a second slide and a connecting piece being connected integrally; and

FIG. 18 is a front view of a hard drive tray provided by some embodiments of the present disclosure.

### LIST OF REFERENCE NUMERALS

1-tray front end body, 11-relief hole, 12-stud, 13-limiting protrusion, 14-limiting portion, 15-fourth ventilation hole, 16-third ventilation hole, 2-first slide, 21-clamping column, 22-mounting hole, 23-fastener, 24-connecting piece, 3-second slide, 4-sheet metal support, 41-support arm cross beam, 42-first support arm, 421-supporting plate, 422-through hole, 43-second support arm, 5-light guide, 6-handle, 61-first buckle, 62-third clamping groove, 63-mounting plate, 64-third mounting hole, 65-first pin shaft, 66-first torsion spring, 67-ventilation slot, 68-first ventilation hole, 69-second ventilation hole, 7-electromagnetic interference shielding elastic piece, 71-middle elastic piece, 711-limiting hole, 72-side connection portion, 73-side elastic piece, 731-projection, 732-bent portion, 8-button, 81-second buckle, 82-pressing portion, 83-mounting portion, 831-mounting arm, 832-fourth mounting hole, 84-second pin shaft, 85-second torsion spring, 9-hard drive, and 10-switch.

### DETAILED DESCRIPTION

The core of the present disclosure is to provide a hard drive tray that is convenient to install and has a simple structure. Another core of the present disclosure is to provide a hard drive assembly including the hard drive tray, which is convenient to assemble with high assembly efficiency. Further another core of the present disclosure is to provide a server including the hard drive assembly which has high assembly efficiency and good maintenance applicability.

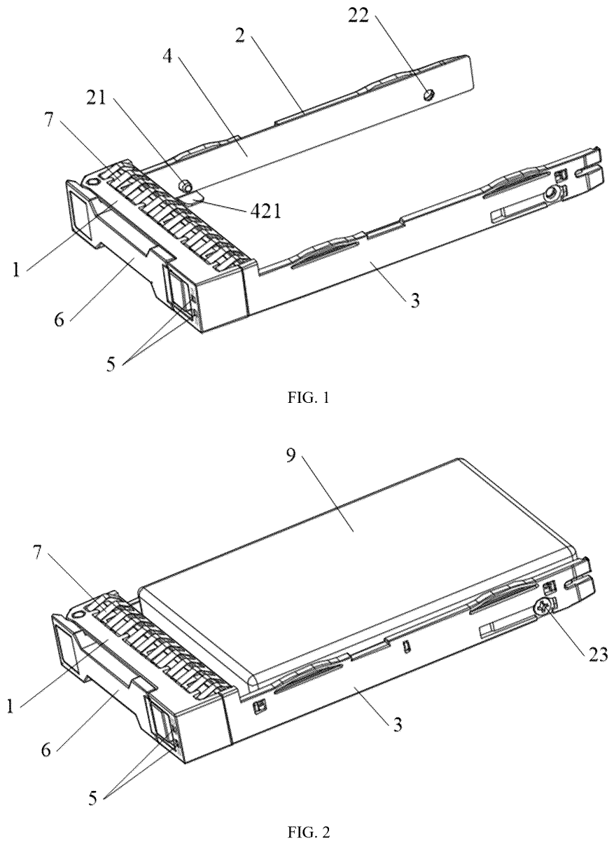

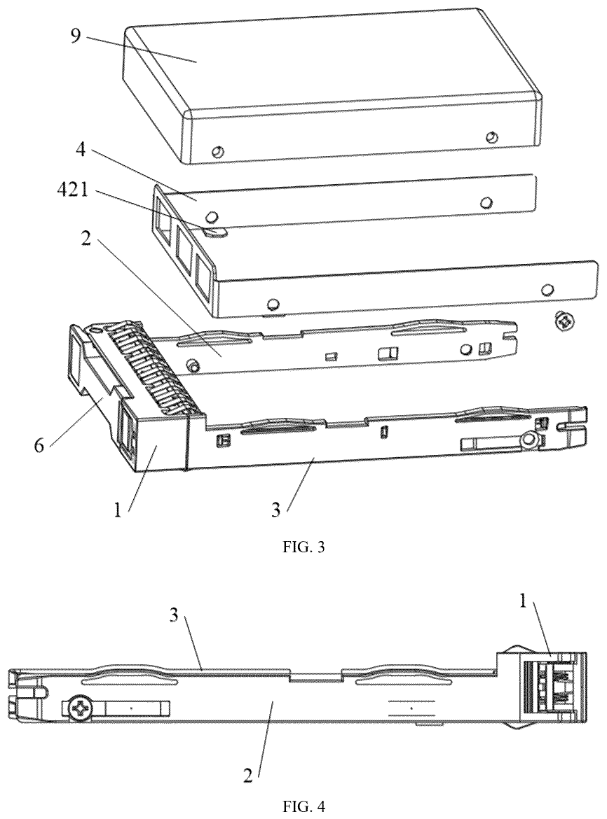

Referring to FIG. 1, FIG. 2 and FIG. 3, some embodiments of the present disclosure provide a hard drive tray including a tray front end body 1, a first slide 2, a second slide 3 and a clamping column 21. The first slide 2 and the second slide 3 are connected to the tray front end body 1, and the first slide 2 and the second slide 3 are disposed opposite to each other with a space being formed therebetween for receiving a hard drive 9. The clamping column 21 is arranged on at least one of the first slide 2 and the second slide 3 and configured for clamping with the hard drive 9. At least one of the first slide 2 and the second slide 3 is provided with a mounting hole 22 which is configured for a fastener 23 to pass therethrough. The fastener 23 is configured to fix the hard drive 9.

It can be understood that the tray front end body 1, the first slide 2 and the second slide 3 are connected together to form an integrated hard drive tray similar to a U-shaped structure. The hard drive tray has an internal space in which the hard drive 9 is received. The first slide 2 and the second slide 3 are configured to limit two sides of the hard drive 9 respectively. During installation, the hard drive 9 is pushed from openings at ends of the first slide 2 and the second slide 3 away from the tray front end body 1 to ride on the first slide 2 and the second slide 3, and continuously pushed until it is installed in place. In this case, the clamping column 21 is clamped into the first clamping groove of the hard drive 9. Then, the fastener 23 is passed through the mounting hole 22 and fixed to the hard drive 9.

As can be seen from the above, in some embodiments of the present disclosure, the clamping column 21 is disposed on at least one of the first slide 2 and the second slide 3. After the hard drive 9 is installed in place, the clamping column 21 is clamped with the corresponding first clamping groove of the hard drive 9, thereby playing a role of assisting in fixing the hard drive 9. Moreover, at least one of the first slide 2 and the second slide 3 is provided with the mounting hole 22 which allows the fastener 23 for fixing the hard drive 9 to pass therethrough. Therefore, when the hard drive 9 is installed in place, the fastener 23 is passed through the mounting hole 22 and connected to the hard drive 9. It thus can be seen that the hard drive tray involves two combined fixing manners, namely clamping of the clamping column 21 with the hard drive 9 and fixing of the fastener 23 with the hard drive 9, thereby realizing the fixation of the hard drive 9 on the hard drive tray. The clamping of the clamping column 21 with the first clamping groove of the hard drive 9 allows for a tool-free installation structure, which only requires that the first clamping groove is aligned with the clamping column 21. Compared with the related art in which the hard drive 9 is fixed completely using screws, the number of fasteners 23 is reduced as the clamping column 21 is used, thereby saving the installation time, improving the assembly efficiency and improving the maintenance applicability. Compared with a bracket for the hard drive 9 without using an installation tool in the related art, the hard drive tray provided in some embodiments of the present disclosure has a simple structure.

That is, the hard drive tray provided by some embodiments of the present disclosure is convenient to install while ensuring reliable fixation of the hard drive 9, thereby reducing the assembly time, and has a simple structure, good applicability, and high practical value.

It needs to be noted that a specific arrangement manner, a relative position relationship and the like of the clamping column 21 and the mounting hole 22 are not limited in the embodiments of the present disclosure as long as the clamping column 21 can be fit with the fastener 23 passing through the mounting hole 22 to fix the hard drive 9.

With continued reference to FIG. 1, in some embodiments, the clamping column 21 is closer to the tray front end body 1 than the mounting hole 22 along a length direction of the first slide 2 or the second slide 3. That is, in comparison, the clamping column 21 is relatively close to the tray front end body 1, and the mounting hole 22 is relatively far away from the tray front end body 1. It can be understood that the closer to the tray front end body 1, the smaller the deformation amount when the first slide 2 and the second slide 3 are deformed away from each other, and the farther away from the tray front end body 1, i.e., the closer to the opening of the hard drive tray, the greater the deformation amount when the first slide 2 and the second slide 3 are deformed away from each other. Therefore, in this embodiment, the clamping column 21 is closer to the tray front end body 1 than the mounting hole 22, which is conducive to clamping the hard drive 9 by the clamping column 21. Moreover, the mounting hole 22 is closer to the opening of the hard drive tray, which is conducive to fixing the hard drive 9, thereby improving the fixation reliability and stability of the hard drive 9.

In some embodiments, the clamping column 21 includes a first clamping column disposed on the first slide 2 and a second clamping column disposed on the second slide 3. That is, in some embodiments, the clamping columns 21 are disposed on both the first slide 2 and the second slide 3, which is conducive to improving the balance of the clamping forces on both sides of the hard drive 9.

It should be noted that the specific number of the first and second clamping columns is not limited in the embodiments of the present disclosure. The number of the first clamping columns and the number of the second clamping columns may each be one, or may each be at least two. The more the number of the first clamping columns and the second clamping columns, the more the positions of clamping the hard drive 9, allowing for more secure fixation of the hard drive 9.

In consideration of the balance of forces exerted on both sides of the hard drive 9, in some embodiments, the first clamping column and the second clamping column are aligned. That is, the first clamping column and the second clamping column are respectively clamped with two first clamping grooves on two sides of the hard drive 9 that are located in the same cross section. This is conducive to further improving the balance of the clamping force exerted on the hard drive 9, and at the same time, facilitating installation.

In addition, in some embodiments, the mounting hole 22 includes a first mounting hole formed in the first slide 2 and a second mounting hole formed in the second slide 3. That is, in some embodiments, both the first slide 2 and the second slide 3 are provided with mounting holes 22, which is conducive to improving the balance of fixing forces exerted on both sides of the hard drive 9.

It should be noted that the specific number of the first and second mounting holes is not limited in the embodiments of the present disclosure. The number of the first mounting holes and the number of the second mounting holes may each be one, or may each be at least two. The greater the number of the first and second mounting holes, the more the positions of fixing the hard drive 9, allowing for more secure fixation of the hard drive 9.

Considering the balance of the forces exerted on both sides of the hard drive 9, in some embodiments, the first mounting hole and the second mounting hole are aligned. That is, the first mounting hole and the second mounting hole are respectively fit and fixed with two fixing holes on the two sides of the hard drive 9 that are located in the same cross section. This is conducive to further improving the balance of the fixing force exerted on the hard drive 9.

In addition, referring to FIG. 1, in order to facilitate the installation of the hard drive 9 and improve the stability of the fixed hard drive 9, in some embodiments, the hard drive tray further includes a supporting plate 421. The supporting plate 421 is connected to at least one of the first slide 2, the second slide 3 and the tray front end body 1. The supporting plate 421 extends to the bottom of the space between the first slide 2 and the second slide 3 and is configured to support the hard drive 9. That is to say, in some embodiments, the supporting plate 421 is provided to support the hard drive 9 from below so that the hard drive 9 is located in a horizontal plane, thereby improving the positioning accuracy of the hard drive 9. Therefore, the fitting and clamping of the clamping column 21 with the first clamping groove of the hard drive 9 is facilitated. Moreover, after the hard drive 9 is fixed, the supporting plate 421 also supports the hard drive 9 to a certain extent so that the hard drive 9 can be fixed more stably. The supporting force of the supporting plate 421 can also counteract a part of the gravity of the hard drive 9, thereby reducing the shear force exerted on the clamping column 21 and the fastener 23, improving the structural stability and prolonging the service life.

It needs to be noted that the specific structure and the specific arrangement manner of the supporting plate 421 are not limited in the embodiments of the present disclosures as long as the supporting plate 421 can extend to the bottom of the space between the first slide 2 and the second slide 3 to support the hard drive 9.

In some embodiments, the supporting plate 421 includes a first supporting plate disposed at the bottom of the first slide 2 and located below the first clamping column, and a second supporting plate disposed at the bottom of the second slide 3 and located below the second clamping column. That is to say, in some embodiments, the supporting plates 421 are disposed at the bottoms of the first slide 2 and the second slide 3, respectively. The first supporting plate is arranged to extend towards the side where the second slide 3 is located and the second supporting plate is arranged to extend towards the side where the first slide 2 is located, thereby supporting the hard drive 9 at two points. Furthermore, the first supporting plate is located below the first clamping column and the second supporting plate is located below the second clamping column. That is, the position where the first supporting plate supports the hard drive 9 is close to the first clamping column, and the position where the second supporting plate supports the hard drive 9 is close to the second clamping column. Thus, in the case of the first supporting plate and the second supporting plate stably supporting the hard drive 9, the first clamping grooves on the two sides of the hard drive 9 can be aligned with the first clamping column and the second clamping column, respectively, so that the first clamping column and the second clamping column can be fit and clamped with the first clamping grooves on the two sides of the hard drive 9, respectively. This is conducive to the rapid installation and positioning of the hard drive 9. A lot of convenience is brought to the installation of the hard drive 9, thereby improving the assembly efficiency.

In addition, when the hard drive tray installed with the hard drive 9 is inserted into a chassis, in order to prevent the hard drive tray from being inserted upside down, in some embodiments, a height of one of the first slide 2 and the second slide 3 is greater than a height of the other. The first slide 2 and the second slide 3 are configured to match a front window structure of the chassis to prevent the hard drive tray from being inserted upside down. As shown in FIG. 4, the height of the first slide 2 is less than the height of the second slide 3. Therefore, in the left view of the hard drive tray shown in FIG. 4, a portion of the second slide 3 higher than the first slide 2 can be seen. It can be understood that the front window structure of the chassis has structures that are respectively fit with the first slide 2 and the second slide 3. In some embodiments, the height of one of the first slide 2 and the second slide 3 is greater than the height of the other such that a height difference is formed between the first slide 2 and the second slide 3. Correspondingly, there is also a height difference between the structures of the front window structure of the chassis that are configured to be respectively fit with the first slide 2 and the second slide 3. In this way, when the hard drive tray is inserted into the chassis, the hard drive tray can be inserted into the front window structure of the chassis only when a position state of the hard drive tray is correct. When the position state of the hard drive tray is incorrect, the hard drive tray cannot be inserted into the front window structure of the chassis. That is, the physical fool-proofing function of the hard drive tray can be realized, thereby preventing the hard drive tray from being inserted upside down. Furthermore, rapid positioning of the hard drive tray during the installation of the hard drive tray is facilitated, thereby improving the production efficiency and the maintenance applicability.

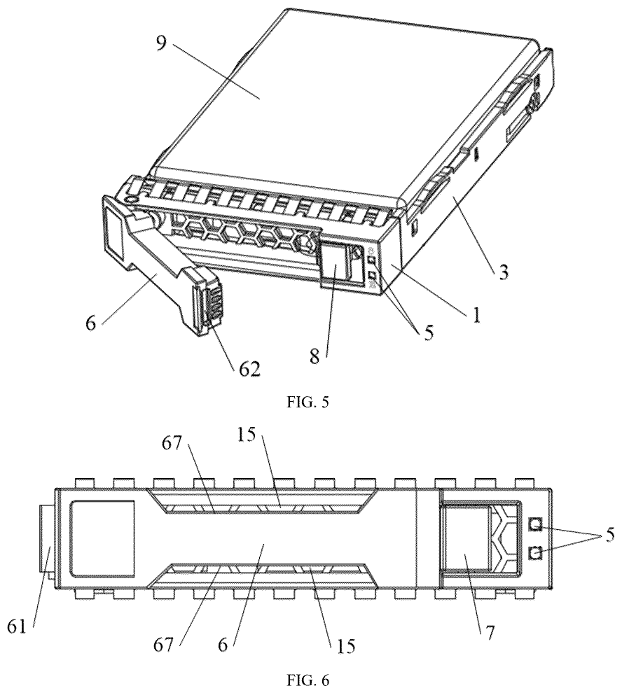

In addition, referring to FIG. 5 and FIG. 6, in some embodiments, a light guide 5 is disposed on the tray front end body 1 at a position corresponding to the second slide 3. A front end face of the light guide 5 is exposed in front of the tray front end body 1 to display a working state of the hard drive 9, while a rear end face of the light guide 5 is configured to match a working indicator light on a back plate of the hard drive 9. It can be understood that the front end face of the light guide 5 refers to the end face of the end of the light guide 5 away from the second slide 3, and the rear end face of the light guide 5 refers to the end face of the end of the light guide 5 facing the side where the second slide 3 is located. The light guide 5 is disposed on the tray front end body 1 at the position corresponding to the second slide 3, which is conducive to allowing the light guide 5 to avoid other structural members disposed on the tray front end body 1, such as a handle 6. Moreover, the front end face of the light guide 5 is exposed in front of the tray front end body 1, which is convenient for the customer to identify the working state of the hard drive 9 and conducive to improving the maintenance applicability.

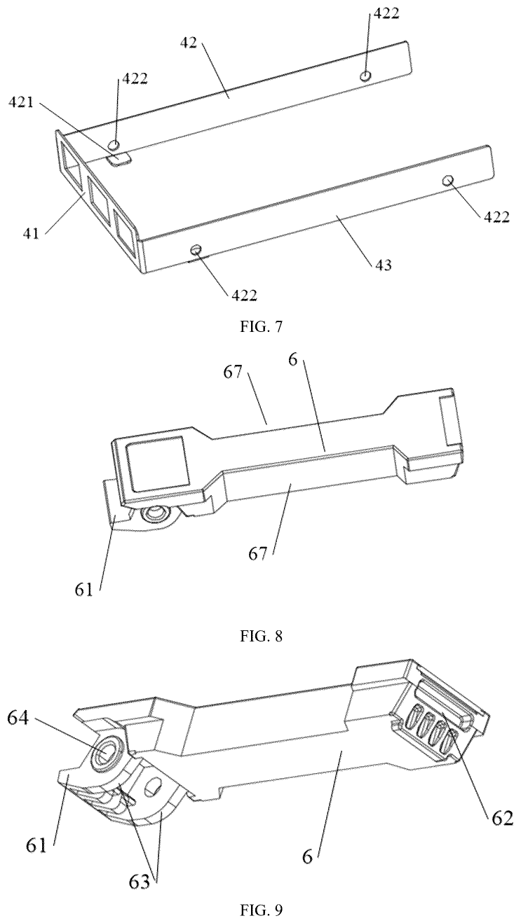

In addition, referring to FIG. 7, in order to improve the structural strength, in some embodiments, the hard drive tray further includes a sheet metal support 4. The sheet metal support 4 includes a support arm cross beam 41, a first support arm 42 and a second support arm 43. The support arm cross beam 41 is of a straight hollowed-out structure and is configured to be connected to a side of the tray front end body 1 facing the first slide 2 and the second slide 3. The first support arm 42 and the second support arm 43 are perpendicularly connected to two ends of the support arm cross beam 41, respectively. The first support arm 42 is in close contact with an inner sidewall of the first slide 2. The second support arm 43 is in close contact with an inner sidewall of the second slide 3. The first support arm 42 and the second support arm 43 are each provided with a through hole 422 configured for the clamping column 21 and the fastener 23 to pass therethrough. It can be understood that, in order to facilitate the installation of the hard drive 9 into the space between the first slide 2 and the second slide 3, in some embodiments, the first slide 2, the second slide 3 and the tray front end body 1 are plastic parts and each have a certain plastic deformation capacity. As a result, the first slide 2, the second slide 3 and the tray front end body 1 have low strength and rigidity and hence insufficient supporting capacity for the hard drive 9. In order to improve the structural strength and rigidity of the hard drive tray, in some embodiments, the sheet metal support 4 is added. The support arm cross beam 41, the first support arm 42 and the second support arm 43 of the sheet metal support 4 are integrally connected, forming an approximately U-shaped structure which is embedded inside the tray front end body 1, the first slide 2 and the second slide 3. Thus, the structural strength of the tray front end body 1, the first slide 2 and the second slide 3 is improved. Both the first support arm 42 and the second support arm 43 are provided with the through holes 422 for the clamping column 21 and the fastener 23 to pass therethrough, so as to avoid affecting the clamping of the clamping column 21 with the hard drive 9 and the fixation of the fastener 23 with the hard drive 9. In addition, the support arm cross beam 41 is of the straight hollowed-out structure so that the weight of the sheet metal support 4 can be reduced. Moreover, locking screws for connecting the sheet metal support 4 and the tray front end body 1 can be conveniently passed through hollowed-out holes and connected to the tray front end body 1 such that the support arm cross beam 41 is held down by the heads of the locking screws.

In addition, in order to improve the structural strength of the above-mentioned supporting plate 421, in some embodiments, the supporting plate 421 is disposed at the bottom of the sheet metal support 4. For example, the supporting plates 421 are disposed at the bottoms of the first support arm 42 and the second support arm 43 corresponding to the clamping columns 21, respectively.

In addition, referring to FIG. 5, FIG. 6 and FIG. 8, in order to facilitate plugging and unplugging of the hard drive tray, in some embodiments, the tray front end body 1 is provided with a handle 6 which can be rotated to open or close. The handle 6 is provided with a first buckle 61 which is configured to be fit with a second clamping groove of a server chassis to limit a position when the handle 6 is closed. When the handle 6 is rotated to open, the first buckle 61 is disengaged from the second clamping groove. That is to say, in some embodiments, with the handle 6, it is convenient for the user to insert the hard drive tray into the chassis or pull the hard drive tray out of the chassis by grasping the handle 6. Furthermore, the handle 6 is provided with the first buckle 61, and after the hard drive tray is installed in place in the chassis, the handle 6 is rotated to close. In this case, the handle 6 drives the first buckle 61 to extend into the second clamping groove of the server chassis such that the first buckle 61 is clamped with the second clamping groove, thereby preventing the hard drive tray from falling out of the chassis. When the hard drive tray needs to be pulled out, the handle 6 is rotated to open. In this case, the first buckle 61 moves together with the handle 6 and thus is disengaged from the second clamping groove. In this case, the hard drive tray can be pulled out of the chassis.

In some embodiments, the handle 6 includes a first end rotatably connected to the tray front end body 1 and a second end clamped with the tray front end body 1. The first buckle 61 is disposed at the first end. It can be understood that when the handle 6 is closed, the second end of the handle 6 is clamped with the tray front end body 1. In this case, it is equivalent to that two ends of the handle 6 are fixed so that the handle 6 remains in a closed state, ensuring that the first buckle 61 is fit with the second clamping groove of the server chassis to limit the position. When the handle 6 needs to be opened, the second end of the handle 6 is unclamped from the tray front end body 1. In this case, the second end of the handle 6 becomes a free end. Therefore, the handle 6 can be rotated to open.

It needs to be noted that the specific connection manner of the handle 6 and the tray front end body 1 is not limited in the foregoing embodiments as long as the handle 6 can be rotated to open or close.

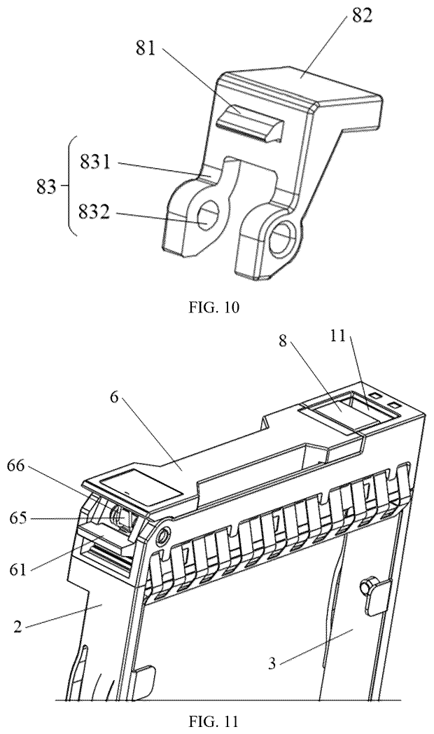

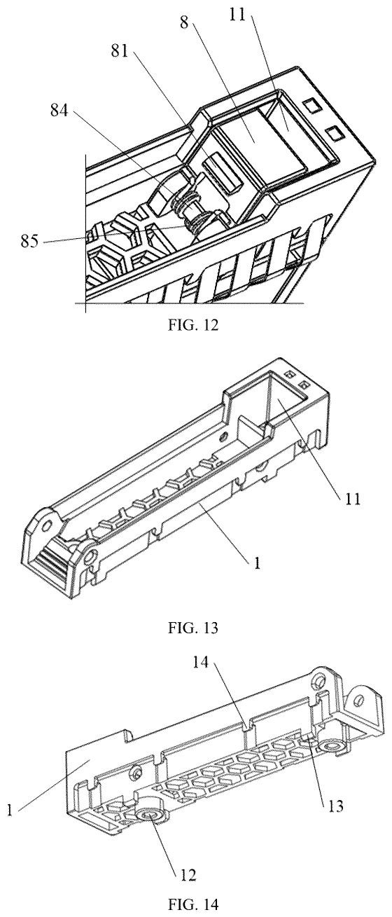

Referring to FIG. 9, FIG. 10, FIG. 11 and FIG. 12, in some embodiments, the first end of the handle 6 includes two mounting plates 63 arranged in parallel. Third mounting holes 64 are formed in the two mounting plates 63 at corresponding positions. A first pin shaft 65 passes through the third mounting holes 64. The first pin shaft 65 is connected to the tray front end body 1 so that the handle 6 can be rotated relative to the tray front end body 1. A first torsion spring 66 is sleeved on the first pin shaft 65 and abutted against each of the handle 6 and the tray front end body 1. The first torsion spring 66 is configured to provide an elastic force to the handle 6 to open the handle 6. The second end of the handle 6 is provided with a third clamping groove 62. The tray front end body 1 is further provided with a button 8. The button 8 is provided with a second buckle 81, a pressing portion 82 and a mounting portion 83. The second buckle 81 is configured to be fit and clamped with the third clamping groove 62 when the handle 6 is closed. The pressing portion 82 is configured to bear a pressing force to disengage the second buckle 81 from the clamping groove. The mounting portion 83 includes two mounting arms 831 arranged in parallel. Fourth mounting holes 832 are formed in the two mounting arms 831 at corresponding positions. A second pin shaft 84 passes through the fourth mounting holes 832. The second pin shaft 84 is connected to the tray front end body 1 so that the button 8 can be rotated relative to the tray front end body 1. The tray front end body 1 is provided with a relief hole 11 (as shown in FIG. 12 and FIG. 13) to avoid a movement range of the button 8. A second torsion spring 85 is sleeved on the second pin shaft 84 and abutted against each of the button 8 and the tray front end body 1. The second torsion spring 85 is configured to provide to the button 8 an elastic force for clamping the second buckle 81 into the clamping groove.

That is to say, in some embodiments, the rotatable button 8 is disposed on the tray front end body 1. When the button 8 is pressed, the button 8 is rotated around the second pin shaft 84 such that the second buckle 81 is driven by the button 8 to disengage from the third clamping groove 62. In this process, the second torsion spring 85 is compressed to store an elastic force. After the second buckle 81 is disengaged from the third clamping groove 62, the button 8 is released, and the second torsion spring 85 can drive the button 8 to reset. After the second buckle 81 is disengaged from the third clamping groove 62, the second end of the handle 6 is unclamped from the tray front end body 1. In this case, under the action of the elastic force of the first torsion spring 66, the handle 6 can be rotated around the first pin shaft 65 to open. In this process, the first buckle 61 moves together with the handle 6 so that the first buckle 61 can move from a position where it is clamped with the second clamping groove of the chassis to a position where it is disengaged from the second clamping groove. In this case, the hard drive tray can be pulled out of the chassis. Naturally, when the hard drive tray is inserted into the chassis, the handle 6 is also in a position where it is rotated to open so that the hard drive tray can be inserted into the chassis. After the hard drive tray is inserted in place, the handle 6 is rotated and the button 8 is pressed such that the second buckle 81 is driven by the button 8 to move to a position where interference with the closing of the handle 6 is avoided. The handle 6 is closed and the button 8 is released. In this case, under the action of the elastic force of the second torsion spring 85, the second buckle 81 is clamped into the third clamping groove 62 at the second end of the handle 6 such that the second end of the handle 6 is clamped with the tray front end body 1. In the process of rotating the handle 6 to close, the handle 6 drives the first buckle 61 to move together such that the first buckle 61 is clamped into the second clamping groove, thereby limiting the positions of the hard drive tray and the chassis and preventing the hard drive tray from falling out of the chassis.

In addition, in consideration of the ventilation of the hard drive tray, in some embodiments, a middle portion of the handle 6 is of a solid structure. Elongated ventilation slots 67 are formed in the handle 6 on two sides of the middle portion, and a fourth ventilation hole 15 is formed in the tray front end body 1. That is to say, in some embodiments, the ventilation slots 67 are formed on both sides of the handle 6 for ventilation to dissipate heat such that the heat generated by the hard drive 9 is dissipated via the ventilation slots 67 after coming out of the fourth ventilation hole 15. This structure makes the handle 6 have high structural strength and prolongs the service life of the handle 6. It needs to be noted that the shape of the fourth ventilation hole 15 is not limited in some embodiments of the present disclosure. The shape of the fourth ventilation hole 15 may be a hexagonal shape, a circular shape or other shapes.

Referring to FIG. 18, in some other embodiments, the following solution may also be possible: a plurality of first ventilation holes 68 arranged at intervals are formed in a middle portion of the handle 6 along a length direction thereof, a plurality of second ventilation holes 69 arranged along the length direction are formed in the handle 6 on two sides of the middle portion, and a third ventilation hole 16 is formed in the tray front end body 1. It needs to be noted that the shapes of the first ventilation hole 68 and the second ventilation hole 69 may be the same or different. For example, as shown in FIG. 18, the first ventilation hole 68 is hexagonal, and the second ventilation hole 69 is triangular. Naturally, in some other embodiments, the first ventilation hole 68 may also be triangular, circular, or in other shapes, and the second ventilation hole 69 may also be circular, hexagonal, or in other shapes. In addition, the shape of the third ventilation hole 16 is not limited in the embodiments of the present disclosure. The shape of the third ventilation hole 16 may be hexagonal, circular, or in other shapes. In this embodiment, the handle 6 is provided with the first ventilation holes 68 and the second ventilation holes 69 for heat dissipation such that the heat generated by the hard drive 9 is dissipated via the first ventilation holes 68 and the second ventilation holes 69 after coming out of the third ventilation hole 16. This structure makes the handle 6 have a good ventilation effect and a good heat dissipation effect, which is conducive to cooling the hard drive 9.

In some embodiments, a pressable switch 10 is disposed on the tray front end body 1 and is clamped with an end of the handle 6 away from the first buckle 61. When the switch 10 is pressed, the handle 6 is unclamped from the switch 10. That is to say, when the handle 6 is closed, the switch 10 is utilized to lock the handle 6 such that the handle 6 remains closed in some embodiments. When the handle 6 needs to be opened, only the switch 10 needs to be pressed. It needs to be noted that the specific clamping structure between the handle 6 and the switch 10 is not limited in the embodiments of the present disclosure as long as the clamping structure between them can be unclamped by pressing the switch 10. It can be understood that when the handle 6 is closed, the clamping structure between the handle 6 and the switch 10 can be clamped. This arrangement manner is convenient to operate.

In addition, referring to FIG. 15 and FIG. 16, in order to prevent electromagnetic interference, in some embodiments, an electromagnetic interference shielding elastic piece 7 is disposed on a rear end face of the tray front end body 1 facing the first slide 2 and the second slide 3 and on two sides of the tray front end body 1, and is of an integrated structure. That is to say, in some embodiments, with the electromagnetic interference shielding elastic piece 7, electromagnetic waves can be prevented from interfering with the hard drive 9. Furthermore, the electromagnetic interference shielding elastic piece 7 is disposed on the rear end face of the tray front end body 1 facing the first slide 2 and the second slide 3 and on the two sides of the tray front end body 1, thereby preventing electromagnetic interference in all directions. In addition, the electromagnetic interference shielding elastic piece 7 is of the integrated structure, which is convenient to install. Thus, the assembly efficiency of the hard drive tray can be improved.

It needs to be noted that the specific structure of the electromagnetic interference shielding elastic piece 7 is not limited in the embodiments of the present disclosure as long as it can prevent electromagnetic interference.

Referring to FIG. 15, in some embodiments, the electromagnetic interference shielding elastic piece 7 includes a middle elastic piece 71, two side connection portions 72 and two side elastic pieces 73. The middle elastic piece 71 is fit with and fixed to the rear end face of the tray front end body 1. The two side connection portions 72 are respectively connected to two sides of the middle elastic piece 71, and are configured to clamp the two sides of the tray front end body 1. The two side elastic pieces 73 are correspondingly connected to the two side connection portions 72 and respectively bent towards sides away from the tray front end body 1, and extend towards sides where the first slide 2 and the second slide 3 are located. A middle portion of each side elastic piece 73 has a projection 731 protruding away from the tray front end body 1, and an end of each side elastic piece 73 away from the side connection portion 72 has a bent portion 732 bent towards a side where the tray front end body 1 is located. The middle elastic piece 71, the two side connection portions 72 and the two side elastic pieces 73 are formed by bending an integral piece, and the electromagnetic interference shielding elastic piece 7 is of a hollowed-out structure as a whole.

It can be understood that since the middle elastic piece 71, the two side connection portions 72 and the two side elastic pieces 73 are formed by bending the integral piece, the fabrication is simple and convenient to implement. Furthermore, since the electromagnetic interference shielding elastic piece 7 is of the hollowed-out structure as a whole, the weight can be reduced on the one hand, and on the other hand, it is conducive to ensuring that the electromagnetic interference shielding elastic piece 7 has better elasticity. The bent portion 732 at the end of the side elastic piece 73 away from the side connection portion 72 can be configured to clamp the side of the support arm cross beam 41 of the sheet metal support 4 away from the tray front end body 1, thereby being conducive to holding down the support arm cross beam 41 on the tray front end body 1.

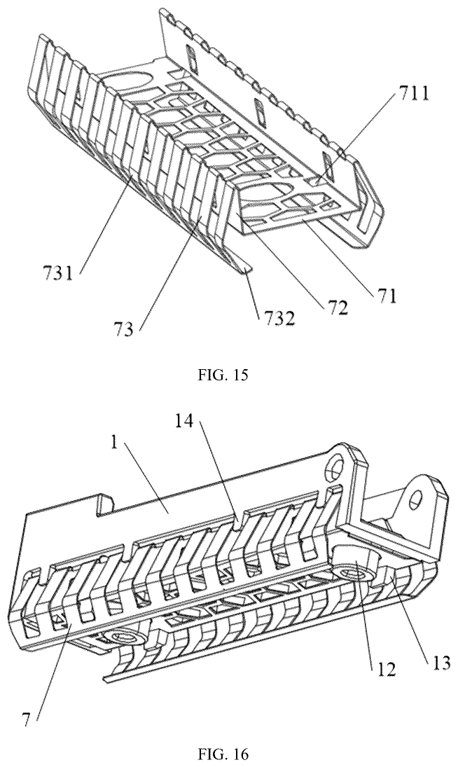

Further, referring to FIG. 14 and FIG. 15, in some embodiments, a limiting protrusion 13 is disposed on the tray front end body 1, and a limiting hole 711 is formed in the middle elastic piece 71 and is fit with the limiting protrusion 13 to limit a position. That is, during installation, the limiting hole 711 of the middle elastic piece 71 of the electromagnetic interference shielding elastic piece 7 is aligned with the limiting protrusion 13 of the tray front end body 1 so that the electromagnetic interference shielding elastic piece 7 can be installed and positioned rapidly.

In addition, in some embodiments, limiting portions 14 are disposed on two sides of the tray front end body 1 and are configured to be fit with the hollowed-out structures of the two side elastic pieces 73 to limit the position. That is to say, when the electromagnetic interference shielding elastic piece 7 is mounted on the tray front end body 1, the limiting portions 14 of the tray front end body 1 are just clamped into the hollowed-out structures of the two side elastic pieces 73 corresponding to the limiting portions 14, thereby limiting the positions of the electromagnetic interference shielding elastic piece 7 and the tray front end body 1.

In addition, the specific manner in which each of the first slide 2 and the second slide 3 is connected to the tray front end body 1 is not limited in the above embodiments as long as each of the first slide 2 and the second slide 3 can be connected to the tray front end body 1.

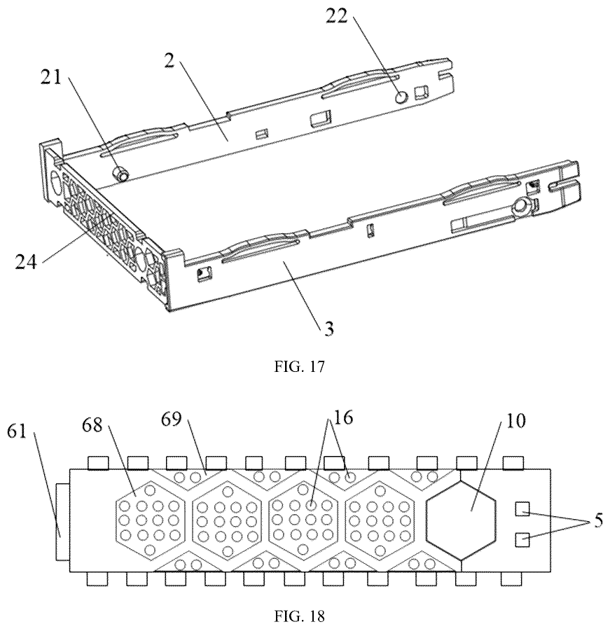

Referring to FIG. 17, in some embodiments, the respective ends of the first slide 2 and the second slide 3 close to the tray front end body 1 are connected to a connecting piece 24 which is connected to the tray front end body 1. That is to say, in some embodiments, the first slide 2 and the second slide 3 are connected together by the connecting piece 24 such that the first slide 2, the second slide 3 and the connecting piece 24 form a U-shaped structure. Both the first slide 2 and the second slide 3 are connected to the tray front end body 1 through the connecting piece 24, and the connection is convenient to implement.

Further, in some embodiments, studs 12 are disposed on the tray front end body 1. Through holes 422 for the studs 12 are formed in the middle elastic piece 71 of the electromagnetic interference shielding elastic piece 7, the connecting piece 24 and the support arm cross beam 41 of the sheet metal support 4, and are configured for the studs 12 to pass therethrough. Locking screws connected to the studs 12 are further included. After the locking screws are tightened with the studs 12, the middle elastic piece 71 of the electromagnetic interference shielding elastic piece 7, the connecting piece 24 and the support arm cross beam 41 of the sheet metal support 4 are held down on the tray front end body 1 by the heads of the locking screws such that the electromagnetic interference shielding elastic piece 7, the connecting piece 24 and the sheet metal support 4 are connected to the tray front end body 1.

In addition, in order to facilitate the installation of the hard drive 9, in some embodiments, the clamping column 21 is an elastic member, or the clamping column 21 is connected with an elastic component. Thus, when a compression force is exerted on the clamping column 21 during the installation of the hard drive 9, the clamping column 21 is contracted. When the hard drive 9 is installed in place, the clamping column 21 is automatically clamped into the first clamping groove of the hard drive 9.

In addition, in order to facilitate detection of whether the hard drive 9 is installed in place, in some embodiments, the hard drive tray further includes a pressure detection component disposed on the first slide 2 and/or the second slide 3. The pressure detection component is configured to detect a pressure between the hard drive 9 and the first slide 2 and/or the second slide 3. Thus, when the pressure between the hard drive 9 and the first slide 2 and/or the second slide 3 does not meet a requirement, a warning is provided in time, thereby ensuring the fixation reliability of the hard drive 9.

In addition to the hard drive tray described above, the present disclosure further provides a hard drive assembly including the hard drive tray disclosed in the foregoing embodiments. The hard drive assembly further includes a hard drive 9 which is disposed between the first slide 2 and the second slide 3 of the hard drive tray. For the structures of other portions of the hard drive 9, please refer to the related arts, which will not be described here redundantly.

The focus of some embodiments of the present disclosure is as follows: the hard drive 9 is arranged in the hard drive tray disclosed in any of the above embodiments, and it has the beneficial effects of the above-mentioned hard drive tray, which will not be repeated here.

In addition to the above-mentioned hard drive tray and hard drive assembly, the present disclosure also provides a server including the hard drive assembly disclosed in the above embodiments. The server further includes a chassis, and the above-mentioned hard drive assembly is inserted into the chassis. For the structure of other parts of the server, please refer to the related technologies, which will not be repeated in this paper.

The focus of some embodiments of the present disclosure lies in: applying the above-mentioned hard drive assembly to the server. The hard drive assembly has high assembly efficiency, which makes the server have good maintenance applicability.

It should also be noted that in this specification, relational terms such as “first” and “second” are only used to distinguish one entity or operation from another entity or operation, and do not necessarily require or imply that there is any such actual relationship or order between these entities or operations.

Each embodiment in this specification is described in a progressive manner, and each embodiment focuses on the differences from other embodiments. For the same or similar parts between the various embodiments, reference may be made to each other.

The hard drive tray, hard drive assembly and server provided by the present disclosure have been introduced in detail above. In this paper, specific examples are used to expound the principle and implementation mode of the present disclosure, and the descriptions of the above embodiments are only used to help understand the method of the present disclosure and its core idea. It should be pointed out that for those of ordinary skill in the technical field, without departing from the principle of the present disclosure, several improvements and modifications can also be made to the present disclosure, and these improvements and modifications also fall within the protection scope of the present disclosure.

1. A hard drive tray, comprising:
a tray front end body;
a first slide connected to the tray front end body,
a second slide connected to the tray front end body and disposed opposite to the first slide, wherein a space configured to receive a hard drive is formed between the first slide and the second slide, the tray front end body, the first slide and the second slide are connected together to form a U-shaped structure, and
a clamping column disposed on at least one of the first slide and the second slide and configured to be clamped with the hard drive,
wherein at least one of the first slide and the second slide is provided with a mounting hole which is configured for a fastener to pass therethrough, and the fastener is configured to fix the hard drive,
wherein the clamping column is closer to the tray front end body than the mounting hole along a length direction of the first slide or the second slide,
wherein during installation, the hard drive is pushed from openings at ends of the first slide and the second slide away from the tray front end body to ride on the first slide and the second slide, and continuously pushed until it is installed in place; the clamping column is clamped into the first clamping groove of the hard drive; then, the fastener is passed through the mounting hole and fixed to the hard drive.

2. (canceled)

3. The hard drive tray according to claim 1, wherein the clamping column comprises:
a first clamping column disposed on the first slide, and
a second clamping column disposed on the second slide,
wherein the first clamping column and the second clamping column are aligned.

4. The hard drive tray according to claim 1, wherein the mounting hole comprises:
a first mounting hole formed in the first slide, and
a second mounting hole formed in the second slide,
wherein the first mounting hole and the second mounting hole are aligned.

5. The hard drive tray according to claim 3, further comprising:
a supporting plate connected to at least one of the first slide, the second slide and the tray front end body, extending to a bottom of a space between the first slide and the second slide, and configured to support the hard drive.

6. The hard drive tray according to claim 5, wherein the supporting plate comprises:
a first supporting plate disposed at a bottom of the first slide and located below the first clamping column, and
a second supporting plate disposed at a bottom of the second slide and located below the second clamping column.

7. The hard drive tray according to claim 1, wherein a height of one of the first slide and the second slide is greater than a height of the other, and the first slide and the second slide are configured to match a front window structure of a chassis to prevent the hard drive tray from being inserted upside down.

8. The hard drive tray according to claim 1, wherein a light guide is disposed on the tray front end body at a position corresponding to the second slide, and a front end face of the light guide is exposed in front of the tray front end body to display a working state of the hard drive, while a rear end face of the light guide is configured to match a working indicator light on a back plate of the hard drive.

9. The hard drive tray according to claim 1, further comprising a sheet metal support which comprises:
a support arm cross beam which is of a straight hollowed-out structure and is configured to be connected to a side of the tray front end body facing the first slide and the second slide,
a first support arm perpendicularly connected to one end of the support arm cross beam and in close contact with an inner sidewall of the first slide, and
a second support arm perpendicularly connected to the other end of the support arm cross beam and in close contact with an inner sidewall of the second slide, wherein the first support arm and the second support arm are each provided with a through hole configured for the clamping column and the fastener to pass therethrough.

10. The hard drive tray according to claim 1, wherein the tray front end body is provided with:
a handle rotatable to open or close, wherein the handle is provided with a first buckle which is configured to be fit with a second clamping groove of a server chassis to limit a position when the handle is closed, and the first buckle is disengaged from the second clamping groove when the handle is rotated to open.

11. The hard drive tray according to claim 10, wherein the handle comprises a first end rotatably connected to the tray front end body and a second end clamped with the tray front end body, wherein the first buckle is disposed at the first end.

12. The hard drive tray according to claim 11, wherein the first end of the handle comprises two mounting plates arranged in parallel; third mounting holes are formed in the two mounting plates at corresponding positions, and a first pin shaft passes through the third mounting holes and is connected to the tray front end body.

13. The hard drive tray according to claim 10, wherein a plurality of first ventilation holes arranged at intervals are formed in a middle portion of the handle along a length direction thereof, a plurality of second ventilation holes arranged along the length direction are formed in the handle on two sides of the middle portion, and a third ventilation hole is formed in the tray front end body.

14. The hard drive tray according to claim 13, wherein a pressable switch is disposed on the tray front end body and is clamped with an end of the handle away from the first buckle, and when the switch is pressed, the handle is unclamped from the switch.

15. The hard drive tray according to claim 10, wherein a middle portion of the handle is of a solid structure; elongated ventilation slots are formed in the handle on two sides of the middle portion, and a fourth ventilation hole is formed in the tray front end body.

16. The hard drive tray according to claim 1, wherein an electromagnetic interference shielding elastic piece is disposed on a rear end face of the tray front end body facing the first slide and the second slide and on two sides of the tray front end body, and is of an integrated structure.

17. The hard drive tray according to claim 16, wherein the electromagnetic interference shielding elastic piece comprises:
a middle elastic piece attached and fixed to the rear end face of the tray front end body,
two side connection portions respectively connected to two sides of the middle elastic piece and configured to clamp the two sides of the tray front end body, and
two side elastic pieces correspondingly connected to the two side connection portions, respectively bent towards sides away from the tray front end body, and extending towards sides where the first slide and the second slide are located, wherein a middle portion of each side elastic piece has a projection protruding away from the tray front end body, and an end of each side elastic piece away from the side connection portion has a bent portion bent towards a side where the tray front end body is located;
the middle elastic piece, the two side connection portions and the two side elastic pieces are formed by bending an integral piece, and the electromagnetic interference shielding elastic piece is of a hollowed-out structure as a whole.

18. The hard drive tray according to claim 17, wherein a limiting protrusion is disposed on the tray front end body, and a limiting hole is formed in the middle elastic piece and is fit with the limiting protrusion to limit a position.

19. A hard drive assembly, comprising a hard drive and the hard drive tray according to claim 1, wherein the hard drive (9) is disposed between the first slide and the second slide of the hard drive tray.

20. A server, comprising a chassis and the hard drive assembly according to claim 19, wherein the hard drive assembly is inserted into the chassis.
